(19) United States
(12) Patent Application Publication
(10) Pub. No.: US 2014/0057433 A1
(43) Pub. Date: Feb. 27, 2014

(54) PIXEL CAPACITORS

(71) Applicants: Paul Cain, Cambridge (GB); Shane Norval, Cambridge (GB); Boon Hean Pui, Cambridge (GB)

(72) Inventors: Paul Cain, Cambridge (GB); Shane Norval, Cambridge (GB); Boon Hean Pui, Cambridge (GB)

(73) Assignee: PLASTIC LOGIC LIMITED, Cambridge (GB)

(21) Appl. No.: 14/110,593

(22) PCT Filed: Apr. 11, 2012
(86) PCT No.: PCT/EP12/56580

§ 371 Date: Nov. 11, 2013

(30) Foreign Application Priority Data
Apr. 11, 2011 (GB) 1106047.2

(51) Int. Cl. H01L 21/768

(52) U.S. Cl. CPC H01L 21/76895
USPC 438/637

(57) ABSTRACT

A technique comprising: forming laterally-extending switching circuitry of a device for controlling an overlying laterally-extending array of pixel conductors of said device; forming an electrically conductive laterally-extending patterned screen over said switching circuitry via a first insulating region, said patterned screen defining holes for receiving conductive interlayer connects between said switching circuitry and said array of pixel conductors; and thereafter: forming a second insulating region over said patterned screen, forming said array of pixel conductors over said patterned screen via said second insulating region for capacitative coupling with said patterned screen, forming through holes through at least said first and second insulating regions at the locations of said holes defined in said patterned screen, and forming said interlayer connects in said through holes; and wherein said patterned screen is configured such that the area of overlap between the array of pixel conductors and underlying conductive elements is substantially constant within a range of lateral positions of the pixel conductors relative to the switching circuitry, which range is greater in a first direction than 40% of the pitch of the pixel conductors in said first direction.

Many electronic devices comprise an array of pixel conductors controlled by switching circuitry.

It has been found that some such devices benefit from capactitatively coupling each pixel conductor with part of the underlying circuitry used to control other pixel conductors of the same array. However, it has now been observed that for the mass production of some devices, the improvement in device performance can vary between devices, and there has been identified the challenge of providing a technique by which a more predictable and consistent improvement in device performance can be achieved.

It is an aim of the present invention to meet this challenge.

There is hereby provided a method, comprising: forming laterally-extending switching circuitry of a device for controlling an overlying laterally-extending array of pixel conductors of said device; forming an electrically conductive laterally-extending patterned screen over said switching circuitry via a first insulating region, said patterned screen defining holes for receiving conductive interlayer connects between said switching circuitry and said array of pixel conductors; and thereafter: forming a second insulating region over said patterned screen, forming said array of pixel conductors over said patterned screen via said second insulating region for capacitative coupling with said patterned screen, forming through holes through at least said first and second insulating regions at the locations of said holes defined in said patterned screen, and forming said interlayer connects in said through holes; and wherein said patterned screen is configured such that the area of overlap between the array of pixel conductors and underlying conductive elements is substantially constant within a range of lateral positions of the pixel conductors relative to the switching circuitry, which range is greater in a first direction than 40% of the pitch of the pixel conductors in said first direction.

According to one embodiment, the projected area of the patterned screen towards the array of pixel conductors is at least about 60% of the area of the footprint of the array of pixel conductors.

According to one embodiment, the projected area of the patterned screen towards the array of pixel conductors is at least about 84% of the area of the footprint of the array of pixel conductors.

According to one embodiment, the projected area of the patterned screen towards a single one of the pixel conductors is at least about 58% of the area of the footprint of a single pixel conductor.

According to one embodiment, the projected area of the patterned screen towards a single one of the pixel conductors is at least about 81% of the area of the footprint of a single pixel conductor.

According to one embodiment, the projected area of the patterned screen towards the array of pixel conductors is equal to the whole area of the footprint of the array of pixel conductors minus an area no greater than about 2000 square microns multiplied by the number of pixel conductors in the array of pixel conductors.

According to one embodiment, the patterned screen is split into an array of strips.

According to one embodiment, said switching circuitry comprises a source/drain electrode layer defining an array of pairs of source/drain electrodes, and wherein each pair of source/drain electrodes comprises a drain electrode wholly enclosed by a source electrode within the plane of said source/drain electrode layer; and wherein said interlayer connects extend down to said drain electrodes.

There is also hereby provided the use of a patterned screen as described above for the purpose of improving the uniformity of pixel performance amongst a plurality of devices.

According to one embodiment, the pixel performance is at least one selected from the group of voltage holding ratio and kickback voltage.

To help understanding of the invention, specific embodiments thereof will now be described by way of example only and with reference to the accompanying drawings, in which:

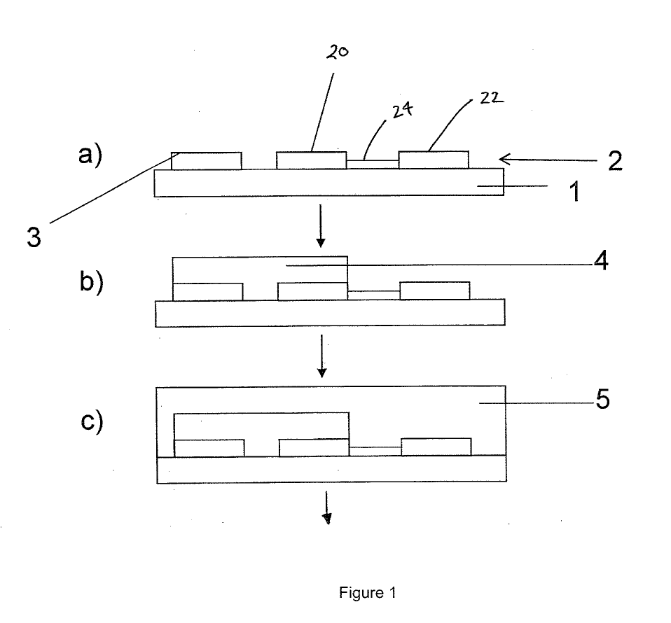

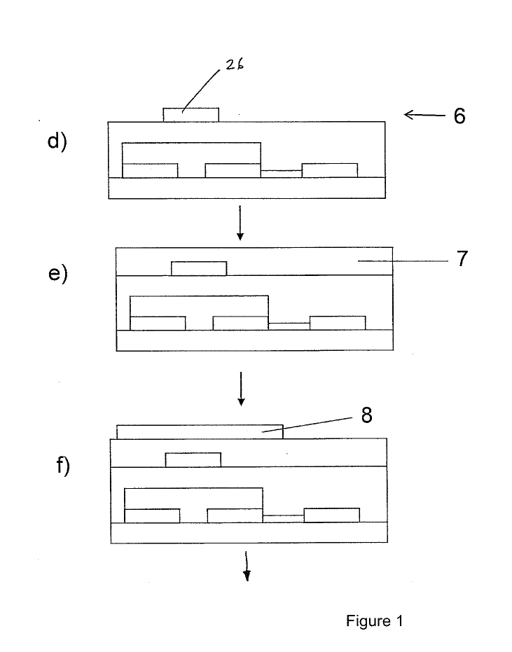

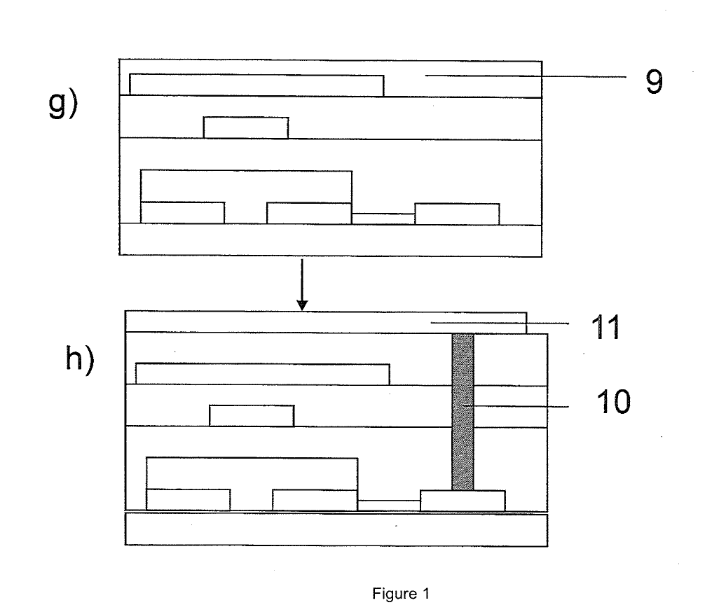

FIGS. 1(a) to (h) illustrate the production of a TFT-controlled pixel conductor array;

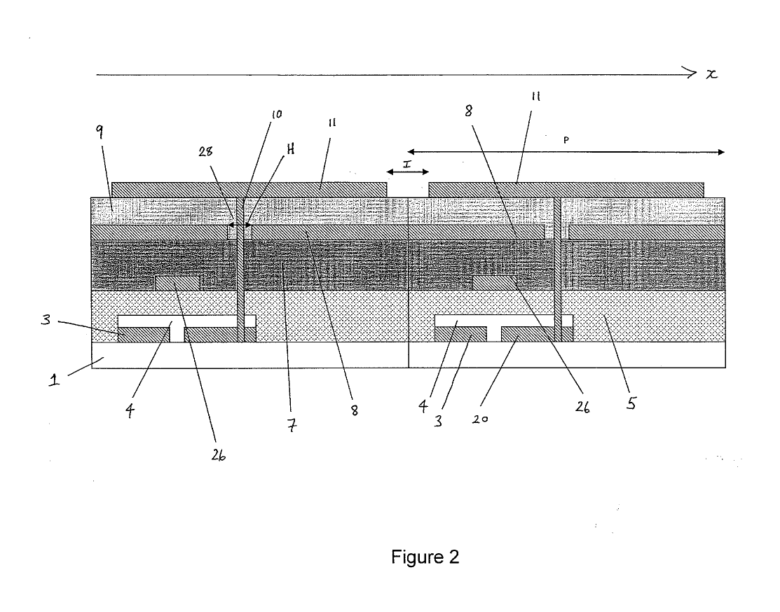

FIG. 2 is a schematic illustration of an example of a TFT-controlled pixel conductor array according to an embodiment of the present invention and produced according to the technique of FIG. 1;

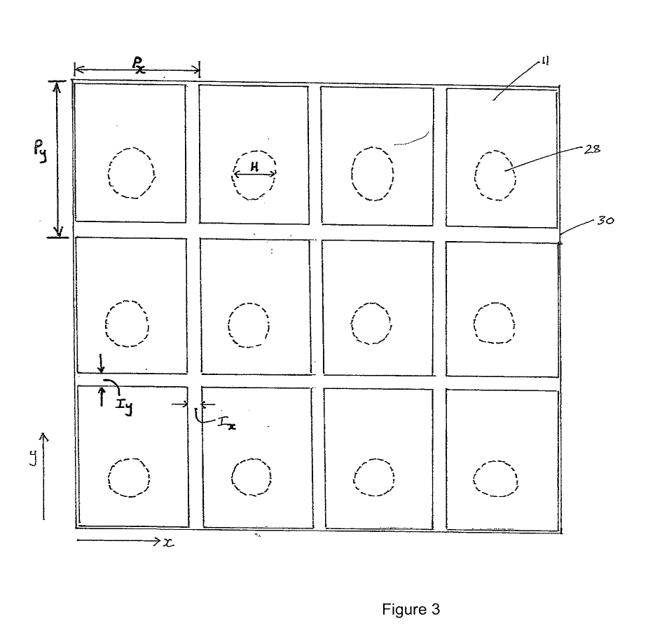

FIG. 3 illustrates the extent of overlap between the pixel conductors and patterned screen in the embodiment of FIG. 2;

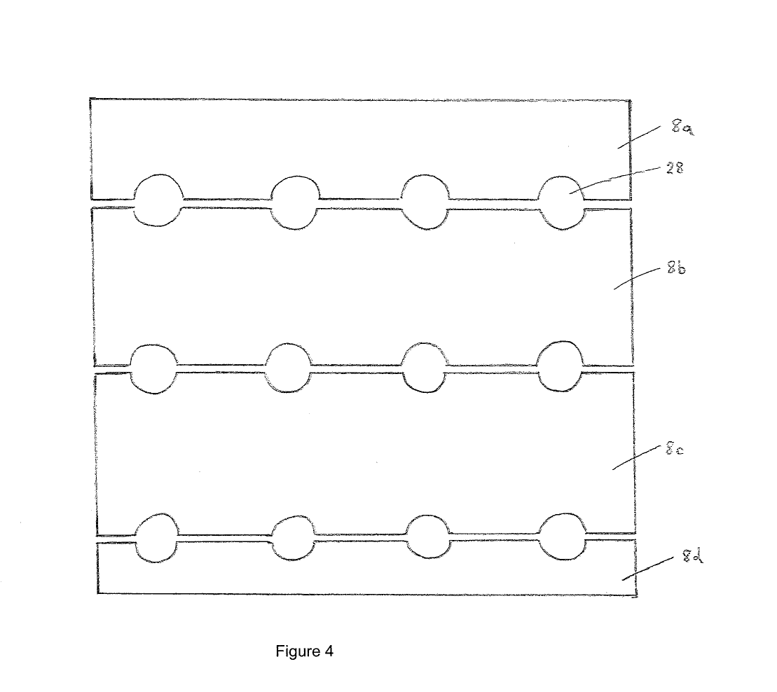

FIG. 4 illustrates the division of the patterned screen into strips according to one variation of the embodiment of FIG. 2;

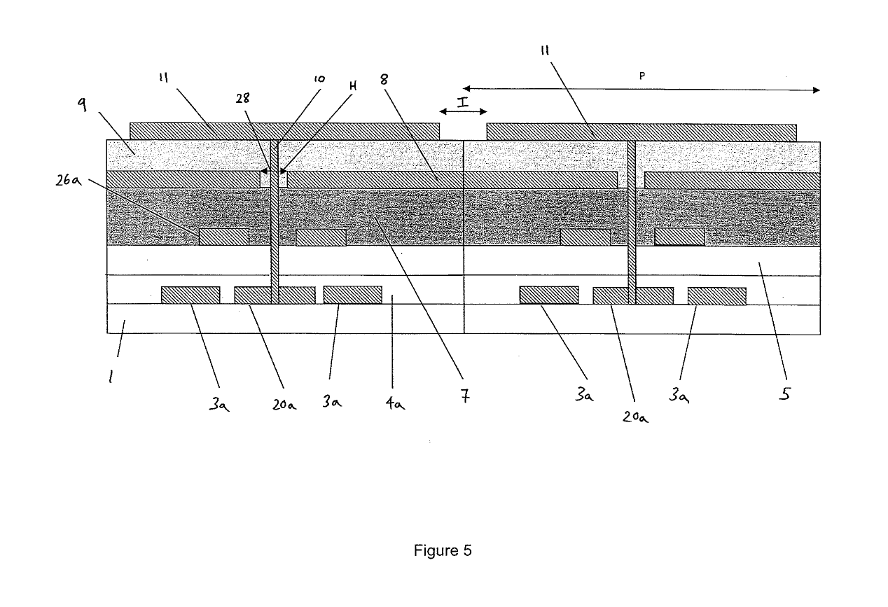

FIG. 5 illustrates another variation of the embodiment of FIG. 2, employing a different array of source and drain electrodes; and

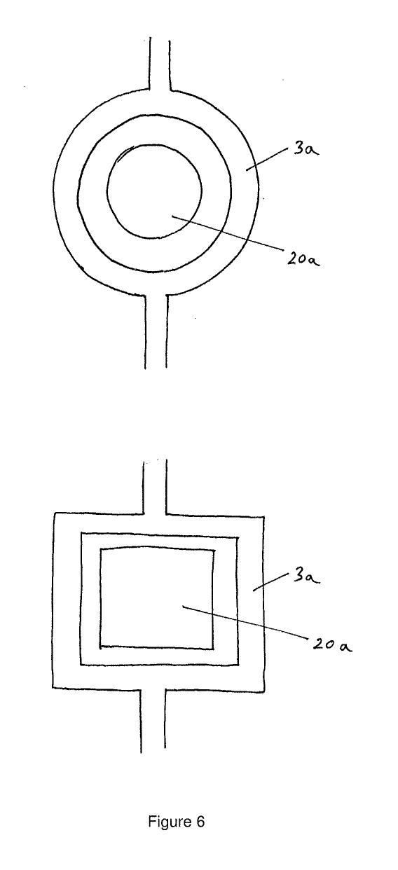

FIG. 6 further illustrates the different array of source and drain electrodes of FIG. 5.

With reference to FIGS. 1 to 3, an embodiment of the present invention is described below in detail, by way of example only.

FIGS. 1 and 2 illustrate an embodiment according to the present invention for the example of producing an array of pixel conductors whose electrical potentials are independently controllable via an underlying array of thin-film transistors (TFTs).

A patterned electrically conductive layer 2 is provided on a support substrate 1. The patterned conductive layer defines for each TFT of the TFT array a source electrode 3, a drain electrode 20, a drain pad 22 and a conductive connection 24 between the drain electrode 20 and the drain pad 22, and also defines a set of electrically conductive lines for addressing the source electrodes of the TFT array. A patterned semiconducting layer 4 is then provided over the patterned conductive layer 2. The patterned semiconductive layer 2 defines a semiconductor channel between each source-drain electrode pair. A patterned or unpatterned insulating layer 5 is then provided over the patterned semiconducting layer 4 and patterned conductive layer 2. The insulating layer 5 provides a gate dielectric region between each of the semiconducting channels and respective gate lines 26 formed in the next step, and also prevents shorts between the patterned conductive layer 2 and overlying conductive elements. A second patterned electrically conductive layer 6 is then provided over the insulating layer 5. This second patterned conductive layer 6 defines the gate lines 26, which each serve as gate electrodes for a respective linear set of TFTs of the array. A patterned conductive screen layer 8 is formed over the underlying layers via a further insulating layer 7. The patterned screen layer 8 covers a large proportion of the footprint 30 of the array of pixel conductors 11 and defines windows 28 at sites where interlayer connects 10 are later to be formed between the drain pads 22 and respective pixel conductors 11. A further insulating layer 9 is then formed over the patterned screen layer 8 and underlying insulating layer 7. Via-hole is then formed through the insulating layers down to the drain pads 22 at the location of the windows 26 in the patterned screen layer. The via-holes are then filled with conducting material to form conductive interlayer connects 10; and the array of pixel conductors 11 are formed over the top insulating layer 9 and in contact with a respective interlayer connect 11.

The support substrate 1 may, for example, be either glass or a planarised polymer film. According to one example, the polymer film is a film of polyethyleneterephtalate (PET) or polyethylenenaphtalene (PEN).

According to one example, the conductive layer 2 is a metallic layer. One example of a metallic layer is a layer of inorganic metal such as gold or silver; or any metal that adheres well to the substrate 1. Another example is a bilayer structure including a layer of metallic material and a seed or adhesion layer in between the layer of metallic material and the support substrate 1. Another example of a material for the conductive layer 2 is a conductive polymer, such as PEDOT/PSS. The patterned conductive layer 2 can, for example, be deposited using solution processing techniques such as spin, dip, blade, bar, slot-die, or spray coating, inkjet, gravure, offset or screen printing. A vapour-deposition technique can also be used to deposit a metallic layer; a sputtering technique is generally preferable to an evaporation technique.

The patterning of the patterned conductive layer 2 may be achieved by, for example, selective removal of selection regions of a continuous, blanket-deposited layer of conductive material by a photolithographic technique or a laser ablation technique. Alternatively, the patterning may be achieved at the time of depositing the conductive material by using ink-jet printing or other direct-write printing technique.

According to one example, the material for the patterned semiconductive layer 4 is a semiconducting polymer such as a polytriarylamine, polyfluorene or polythiophene derivative. The semiconducting layer 4 is patterned to better prevent leakage current between adjacent TFTs. The patterning can be achieved by using a technique such as laser ablation to remove selected portions of a continuous layer deposited by a blanket deposition technique such as spin coating. Alternatively the patterning can be achieved at the time of depositing the semiconducting layer by using a printing technique such as inkjet printing, soft lithographic printing (J. A. Rogers et al., Appl. Phys. Lett. 75, 1010 (1999); S. Brittain et al., Physics World May 1998, p. 31), or screen printing (Z. Bao, et al., Chem. Mat. 9, 12999 (1997)). A typical thickness for the semiconducting layer in the final device is on the order of 50-100 nm.

Polyisobutylene, polymethylmethacrylate, polystyrene or polyvinylphenol are examples of materials for the gate dielectric layer 5. The gate dielectric material may be deposited in the form of a continuous layer, by e.g. techniques such as spray, blade or spin coating. Spin coating is generally preferable. A typical thickness for the gate dielectric region 5 is between 150-1000 nm. The gate dielectric region 5 may either comprise a single layer or a stack of multiple layers. According to one example, the dielectric region comprises a double-layer structure with a layer of relatively low dielectric constant (k) material in contact with the semiconducting layer, and a relatively high-k material deposited on top of the relatively low-k material. According to another example, on top of the high-k dielectric material is deposited a further dielectric layer that facilitates the deposition of the gate lines 26, such as a layer of polyvinylphenol in the case of forming the gate lines 26 from a metal ink.

According to one example, the gate lines 26 are formed from a conducting polymer, such as polyethylenedioxythiophene doped with polystyrene sulfonic acid (PEDOT/PSS). According to another example, the gate lines 26 are formed from a metallic material, such as gold. According to one example, the gate lines 26 are formed from a printable liquid containing inorganic nanoparticles of silver or gold. The pattern of the gate lines is achieved by selective removal of selected portions of a continuous layer of the gate line material, or is achieved at the time of depositing the gate line material by using a direct-write technique such as ink-jet printing.

In the case that the gate lines 26 are formed from a printable liquid, the electrical conductivity of gate lines 26 can be increased by a subsequent annealing process. According to one example, this annealing process is carried out with an IR laser beam. Ultraviolet radiation or thermal annealing may also be used for some metal inks.

According to one example, the dielectric layer 7 formed over the gate lines 26 is a layer of an organic dielectric material or a layer of organic-inorganic hybrid dielectric material. The layer of dielectric material 7 may, for example, be a layer of chemical vapour deposited parylene or a layer of SU-8, which also has use as a negative photoresist material. According to one example, a stack of layers of dielectric material are deposited at this stage, including layers of material such as solution coated polystyrene or PMMA. These layers of dielectric material may be coated by any large area coating method, such as, but not limited to, spin coating, spray coating, or blade coating. According to one example, the thickness of the dielectric layer 7 over the gate lines 26 is in the range of 0.1-20 μm, more specifically in the range of 1 to 12 μm and yet more specifically in the range of 5-10 μm.

The dielectric layer 7 formed over the gate lines 26 provides electrical isolation to prevent shorts between the patterned conductive screen 8 and the gate lines 26. The patterned conductive screen can be formed by depositing a continuous layer of conductive material, and then removing selected portions of the continuous layer by e.g. photolithography to form the windows 28 before depositing dielectric layer 9. According to one example, the patterned conductive screen is a metal layer, and sputtering is used to deposit a continuous layer of the metal before patterning by photolithography. Screen printing, spin coating and evaporation are other examples that could be used for depositing a continuous layer of a conductive material.

The material for the dielectric layer 9 deposited over the patterned conductive screen 8 is selected with view to faciliating the formation of the overlying array of pixel conductors 11.

According to one example, the via hole used to provide the interlayer connect 10 is formed using an excimer laser. Other methods include mechanical punching.

The material used to fill the via-holes and form the pixel conductors 11 need not be highly conductive. According to one example, a conductive polymer is used, such as PEDOT/PSS. According to one example, the conductive material is deposited using solution processing techniques such as spin, dip, blade, bar, slot-die, or spray coating, inkjet, gravure, offset or screen printing. The pattern of the array of pixel conductors 11 can be achieved by the application of photolithography or laser ablation to a continuous layer of the pixel conductor material. Alternatively, the pattern can be achieved at the time of depositing the pixel conductor material by using, for example, a direct-write printing technique. For the latter, a surface energy pattern can be used to assist the formation of a patterned layer of pixel conductor material. In more detail, the surface energy of the underlying dielectric layer 9 is modified in selected regions in such a way as to better confine the spread of drops of pixel conductor material and better achieve a well-defined array of laterally isolated pixel conductors 11.

Depositing the pixel conductor material from a liquid can be preferable from the point of view of also reliably filling the via-holes and creating reliable conductive connections 10 between the drain pads 22 and respective pixel conductors 11. However, a vapour deposition process can also be used. A sputtering technique is generally preferable over an evaporation process. Where the pixel conductors are patterned by laser ablation of a sputtered or evaporated metal layer, a pico-second laser may be used. According to one example, the use of a sputtered or evaporated layer for the array of pixel conductors 11 is employed in combination with a separate process for filling the via-holes with conductive material.

According to one example, the array of pixel conductors 11 is formed with the aim of achieving a regular pitch, but a regular pitch may not be ultimately possible because of distortions arising from the production process.

The patterned conductive screen 8 electrically shields the pixel conductors 11 from all of the conductive elements underlying the patterned conductive screen 8 (except at the locations of the windows 28 defined in the patterned screen layer 8 to allow the formation of the interlayer connects 10 between the drain pads 22 and the pixel conductors 11). This architecture serves to minimise capacitative coupling between the pixel conductors 11 and any conductive elements at a level lower than the patterned conductive screen 8. Accordingly, the only underlying conductive element with which the pixel conductors exhibit substantive capacitative coupling is the patterned conductive screen 8, and because this conductive screen 8 extends over substantially the whole of the footprint 30 of the array of pixel conductors 11, variation in the position of the pixel conductors 11 relative to the conductive elements underlying the patterned conductive screen 8 (which variation can be unavoidable because of unpredictable distortions caused by the production process) has minimal effect on the degree of capacitative coupling between the pixel conductors 11 and underlying conductive elements. This architecture therefore has the effect of stabilizing the pixel performance, substantially regardless of the lateral position of the pixel conductors relative to the underlying conductive layers.

According to one example, the array of pixel conductors exhibit a pixel pitch (P) in the x- and y-directions of about 113 microns with a pixel gap (I) of about 10 microns between each pixel conductor 11 in both the x- and y-directions. The windows 28 defined in the patterned conductive screen each have a diameter (H) of about 50 microns (i.e. a maximum dimension (H) of about 50 microns in both the x and y directions).

The example of a very simple 4×3 array of pixel conductors 11 is illustrated in FIG. 3. FIG. 3 also shows in dashed lines the x-y location of the windows 28 defined in the underlying conductive screen 8. The footprint 30 of the array of pixel conductors 11 is the area of the smallest imaginary square or rectangular shape that encompasses all of the pixel conductors 11; or in other words, is the area bound by an imaginary perimeter line following the outer edges of the outer pixel conductors. The projected area of the conductive screen 8 onto the array of pixel conductors 11 is equal to the footprint 30 of the array of conductors minus the combined area of the windows 28, which is expressed as [PₓP_{y}−π(H/2)²] where Pₓ is the pixel pitch in the x-direction and P_{y} is the pixel pitch in the y-direction, and H is the diameter of the generally circular windows 28. According to one example in which Px and Py are both 113 microns and H is 50 microns, the projected area of the patterned screen towards the array of pixel conductors is about 84% of the footprint 30 of the array of pixel conductors 11.

The projected area of the conductive screen 8 onto any single one of the pixel conductors 11 is equal to the footprint of a single pixel conductor minus the area of a single window 28, which is expressed as [(Pₓ-Iₓ)(P_{y}-I_{y})−π(H/2)²] where Pₓ, P_{y}, and H are as defined above, and Iₓ and I_{y} are the distances between adjacent pixel electrodes in the x and y directions, According to the example mentioned above in which Px and Py are both 113 microns, H is 50 microns, and Iₓ and I_{y} are both 10 microns: the projected area of the patterned screen onto any single one of the pixel conductors 11 is about 81% of the footprint of a single pixel conductor 11.

The range of positions in the x-direction of the pixel conductors 11 within which there is substantially no change in capacitive coupling between the pixel conductors and underlying conductive elements whilst achieving an electrical connection with the respective drain pads is given by the expression:

Pₓ-Iₓ-H (or P_{y}-I_{y}-H for the y-direction)

and the said range of positions expressed as a percentage of the pixel pitch in the x-direction is given by the expression:

(PₓIₓ-H)×100/Pₓ(or (P_{y}-I_{y}-H)×100/P_{y} for the y-direction)

Where Pₓ and P_{y} are as defined above, and Iₓ and I_{y} are the distances between adjacent pixel electrodes in the x and y directions, respectively.

For the above example in which Px=Py=113 microns, Ix=Iy=10 microns and H=50 microns, said range of positions of the pixel conductors in both the x-direction and the y-direction is about 46% of the pixel pitch (P) in the x-direction or y-direction.

The relatively large windows 28 defined by the patterned conductive screen 8 make it possible to maintain low tolerance or the subsequent patterning of the pixel electrodes by e.g. laser processing, screen printing or photolithography. For processes where the windows 28 in the patterned conductive screen 8 can be made smaller, said range of positions of the pixel conductors 11, and therefore the distortion tolerance, will be even greater.

In an active matrix display device with a TFT array of the kind described above, the gate lines 26 are activated sequentially. Maintaining the voltages at the pixel conductors 11 associated with one gate line at a relatively constant level during the whole of the addressing cycle (i.e. also for the period of addressing the other gate lines) is desirable in order to maintain an image, particularly in the case of greyscale devices.

In voltage controlled devices such as liquid crystal or electronic paper, each pixel conductor 11 and the overlying COM plane (not shown) on the opposite side of the display media together form a parallel plate capacitor providing a reservoir of charge. This capacitance is augmented with the kind of architecture described above by the capacitative coupling between the pixel conductors 11 and the patterned conductive screen 8. This additional capacitative coupling also helps to reduce the so-called kickback voltage, which can arise due to parasitic gate-to-source/drain capacitance of the TFTs. When the gate voltage is switched from its ON value to its OFF value at the end of the pixel charging cycle, the pixel voltage can tend to follow the switching of the gate voltage and changes by an amount ΔVₚ. This effect is generally undesirable, and can be reduced for a given TFT design by increasing the value of the pixel capacitance, Increasing the pixel capacitance also helps to improve the voltage holding ratio, and thereby increase the uniformity of the display.

The pixel capacitors defined by the pixel conductors 11 and the patterned conductive screen 8 are of particular use in display devices with relatively thick display media such as electrophoretic media (or otherwise referred to as electronic paper). The relatively large thickness of this kinds of display media leads to a relatively low degree of capacitative coupling between the pixel conductors 11 and an overlying COM plane (not shown), and the pixel capacitors between the pixel conductors 11 and the underlying patterned conductive screen 8 have a relatively large role in e.g. reducing kickback voltage.

According to one variation of the above-described technique, the patterned screen layer is split up into parallel strips (8a, 8b, 8c, 8d in FIG. 4). Each pair of adjacent strips together define the windows 28 for a respective row of interlayer connects 10. The gap between the strips 8a, 8b, 8c and 8d can be sufficiently small that the impact of the gaps on the above-mentioned screening function of the patterned conductive screen is zero or negligible. This splitting of the patterned screen into strips has the advantage that it better enables the producer of the device to deal with any electrical shorts that might happen to arise between the patterned conductive screen 8 and the underlying gate lines 26.

According to another variation of the above-described technique illustrated in FIGS. 5 and 6, each set of interdigitated source and drain electrodes 3, 20 and accompanying drain pad 22 are replaced by a drain electrode 20a and a source electrode 3a that wholly encloses the drain electrode 20a within the plane of the conductive layer that defines the source and drain electrodes. The interlayer connects are formed directly between the respective drain electrode 20a and the respective pixel conductor 11. As shown in FIG. 6, the source and drain electrodes 3a, 20a could have a circular design or a more angular design. The gate lines 26a are similarly modified to include parts that follow the shape of the channel between the source and drain electrodes 3a, 20a and encircle the interlayer connect 10.

The above-described alternative arrangement for the source and drain electrodes has the following advantages. The absence of a drain pad 22 simplifies the design of the TFT array and facilitates increasing the number of TFTs per unit area and thereby increasing the resolution of the pixellated display device. Furthermore, because each source electrode 3a is designed to wholly enclose the respective drain electrode 20a, there is less concern about parasitic leakage between source and drain electrodes of adjacent TFTs, which better enables the use of a continuous (unpatterned) semiconductor layer 4a extending over the source/drain electrodes of all of the TFTs (instead of the patterned semiconductor layer 4 illustrated in FIGS. 1 and 2). Furthermore, although not shown in FIGS. 1 and 2, the use of drain pads 22 is accompanied by an array of overlying com lines at the same level as the gate lines 26 and extending substantially parallel to the gate lines 26. The absence of drain pads 22 in the alternative arrangement of FIG. 5 is accompanied by the absence of such com lines, which eliminates any concern about intralayer electrical shorts between com lines and gate lines 26.

The above described technique is of particular use in devices fabricated on plastic substrates. Plastic substrates can be particularly susceptible to unpredictable distortion occurring under the high temperature and high humidity conditions associated with efficient production processes. The distortion (i.e. dimensional changes) may be different for each axis of the substrate.

The present invention is not limited to the foregoing examples. Aspects of the present invention include all novel and/or inventive aspects of the concepts described herein and all novel and/or inventive combinations of the features described herein.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. A method, comprising: forming laterally-extending switching circuitry of a device for controlling an overlying laterally-extending array of pixel conductors of said device; forming an electrically conductive laterally-extending patterned screen over said switching circuitry via a first insulating region, said patterned screen defining holes for receiving conductive interlayer connects between said switching circuitry and said array of pixel conductors; and thereafter: forming a second insulating region over said patterned screen, forming said array of pixel conductors over said patterned screen via said second insulating region for capacitative coupling with said patterned screen, forming through holes through at least said first and second insulating regions at the locations of said holes defined in said patterned screen, and forming said interlayer connects in said through holes; and wherein said patterned screen is configured such that the area of overlap between the array of pixel conductors and underlying conductive elements is substantially constant within a range of lateral positions of the pixel conductors relative to the switching circuitry, which range is greater in a first direction than 40% of the pitch of the pixel conductors in said first direction.

2. A method according to claim 1, wherein the projected area of the patterned screen towards the array of pixel conductors is at least about 60% of the area of the footprint of the array of pixel conductors.

3. A method according to claim 2, wherein the projected area of the patterned screen towards the array of pixel conductors is at least about 84% of the area of the footprint of the array of pixel conductors.

4. A method according to claim 1, wherein the projected area of the patterned screen towards a single one of the pixel conductors is at least about 58% of the area of the footprint of a single pixel conductor.

5. A method according to claim 4, wherein the projected area of the patterned screen towards a single one of the pixel conductors is at least about 81% of the area of the footprint of a single pixel conductor.

6. A method according to claim 1, wherein the projected area of the patterned screen towards the array of pixel conductors is equal to the whole area of the footprint of the array of pixel conductors minus an area no greater than about 2000 square microns multiplied by the number of pixel conductors in the array of pixel conductors.

7. A method according to claim 1, wherein the patterned screen is split into an array of strips.

8. A method according to claim 1, wherein said switching circuitry comprises a source/drain electrode layer defining an array of pairs of source/drain electrodes, and wherein each pair of source/drain electrodes comprises a drain electrode wholly enclosed by a source electrode within the plane of said source/drain electrode layer; and wherein said interlayer connects extend down to said drain electrodes.

9. A use of a patterned screen as recited in claim 1 for the purpose of improving the uniformity of pixel performance amongst a plurality of devices.

10. A use according to claim 9, wherein the pixel performance is at least one selected from the group of voltage holding ratio and kickback voltage.
